(19) United States
(12) Patent Application Publication
(10) Pub. No.: US 2011/0032730 A1
(43) Pub. Date: Feb. 10, 2011

(54) SAMPLING CIRCUIT AND CONTROL METHOD

(76) Inventor: Wen-Chung Yeh, Hsin-Chu (TW)

Correspondence Address: NORTH AMERICA INTELLECTUAL PROPERTY CORPORATION, P.O. BOX 506, MERRIFIELD, VA, 22116, US

(21) Appl. No.: 12/640,007

(22) Filed: Dec. 17, 2009

(30) Foreign Application Priority Data
Aug. 4, 2009 (TW) 098126179

(51) Int. Cl. H02M 3/335; H03K 17/00

(52) U.S. Cl. 363/21.01; 327/94

(57) ABSTRACT

An embodiment provides a sampling circuit, which has a sampling capacitor and a voltage compensation circuit. The voltage compensation circuit has a reference capacitor and a compensation circuit. The sampling capacitor samples a voltage signal and memorizes the signal as a sampling signal. The reference capacitor memorizes a reference signal with a predetermined value. The compensation circuit changes the reference signal with a recovery amount to recover the reference signal to the predetermined value, and simultaneously changes the sampling signal with an adjustment amount.

### BACKGROUND OF THE INVENTION

1. Field of the Invention

The present invention is related to a sampling circuit and the corresponding control method, and more particularly, to a sampling circuit and the corresponding control method for a power supply.

2. Description of the Prior Art

Sampling circuit is a common apparatus employed extensively in analog circuit applications such as the power supply. The basic sampling circuit is composed of a switch and a capacitor. When sampling, the sampling circuit turns on the switch, the storage end of the capacitor can then receive the sampled voltage signal to proceed charging/discharging accordingly, and subsequently the switch is turned off so the capacitor stores/holds a sampled voltage value. The sampled signal can then be provided for the other circuits to be used in different demands. In other words, sampling and holding a voltage signal can be accomplished by controlling the switch of the sampling circuit with a pulse signal.

However, practically speaking, the capacitor used in such a sampling circuit is prone to leakage; the longer the sampled signal is held in the capacitor, the worse the leakage becomes. To resolve the said leakage issue often requires utilizing capacitors of large area (i.e. high capacitance), and the production cost is increased considerably as the consequence. Therefore, it is clear that there remains substantial room for improvement of overcoming the leakage concern in the current processing without involving excessive cost.

### SUMMARY OF THE INVENTION

The present invention discloses a sampling circuit. The sampling circuit comprises a sampling capacitor and a voltage compensation circuit. The sampling capacitor is for sampling a voltage signal to store a sampled signal. The voltage compensation circuit comprises a reference capacitor and compensation circuit. The reference capacitor is for storing a reference signal, wherein the reference signal has a predetermined voltage level. The compensation circuit is for adjusting the voltage level of the reference signal of the reference capacitor by a recovering level so the voltage level of the reference signal of the reference capacitor is recovered back to the predetermined voltage level, and subsequently adjusting a voltage level of the sampled signal by an adjusting level; wherein a ratio between the recovering level and the adjusting level is constant.

The present invention further discloses a control method, for controlling a switching-mode power supply, the switching-mode power supply comprising a transformer coupled to an input voltage source, a switch controlled by the transformer to charge or discharge for generating an output voltage source. The control method comprises providing a sampling capacitor; sampling a voltage signal with the sampling capacitor and stores a sampled signal accordingly; adjusting a voltage level of the sampled signal stored in the sampled capacitor by an adjusting level prior sampling the voltage signal again; and adjusting a voltage level of the output voltage source according the adjusted sampled signal.

The present invention further discloses a control method. The control method comprises providing a sampling capacitor; sampling a voltage signal with the sampling capacitor and storing a sampled signal accordingly; adjusting a voltage level of the sampled signal stored in the sampled capacitor by an adjusting level prior sampling the voltage signal again.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating the primary side controlled switching-mode power supply.

FIG. 2 is a waveform diagram illustrating the voltage signals at different nodes of the power supply.

FIG. 3 is a diagram illustrating an embodiment of sampling circuit of switch controller of the present invention.

FIG. 4 is a waveform diagram illustrating the signals of sampling circuit of switch controller in FIG. 3.

FIG. 5 is diagram illustrating the sampling circuit of switch controller according to another embodiment of the present invention.

### DETAILED DESCRIPTION

Further objects of the present invention and more practical merits obtained by the present invention will become more apparent from the description of the embodiments which will be given below with reference to the accompanying drawings. For explanation purposes, components with equivalent or similar functionalities are represented by the same symbols. Hence components of different embodiments with the same symbol are not necessarily identical. Here, it is to be noted that the present invention is not limited thereto.

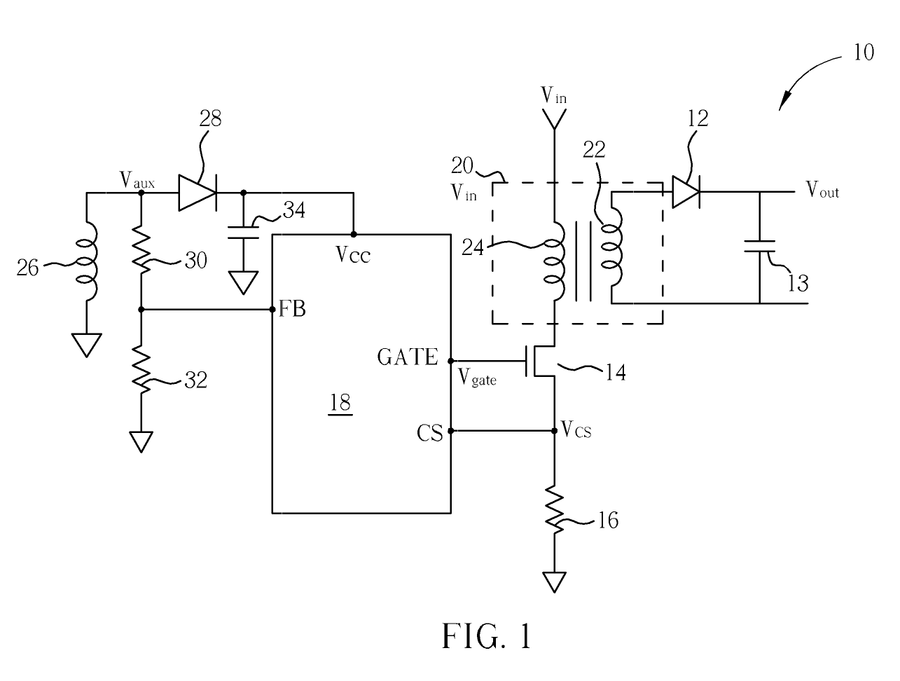

FIG. 1 is a diagram illustrating the primary side controlled switching-mode power supply. Power supply 10 is of a fly-back structure. Primary winding 24 of transformer 20, power switch 14, and current detection resistor 16 are coupled in series between input voltage source V_{IN} and a ground end. When switch controller 18 turns on power switch 14, primary winding 24 starts charging; when switch controller 18 turns off power switch 14, transformer 20 discharges via secondary winding 22 and auxiliary winding 26. Rectifier 12 and capacitor 13 rectify the electrical energy discharged by secondary winding 22 and then provide an output voltage source V_{OUT} to the load accordingly. In addition, after rectifying the electrical energy discharged by auxiliary winding 26, rectifier 28 and capacitor 34 also provide an operation power to pin V_{CC} of switch controller 18. Voltage divider consisting of resistors 30 and 32 is used for dividing the reflective voltage of auxiliary winding 26 and providing a feedback signal transmitted into pin FB of switch controller 18. The reflective voltage of auxiliary winding 26 approximately corresponds to the voltage drop across secondary winding 22. Therefore by utilizing a voltage divider, switch controller 18 is able to acquire the voltage drop across secondary winding 22 and then controls the operation of power switch 14 accordingly. The term “primary side control” mentioned above indicates that the voltage drop across of the secondary winding is not monitored directly from the secondary winding, but via the first winding or the auxiliary winding, and accordingly a corresponding signal is transmitted to pin FB of the switch controller for controlling the power switch.

For detecting the precise voltage drop across the secondary winding, switch controller 18 requires a sampling circuit for acquiring the voltage level of the auxiliary winding and for holding the sampled voltage signal for certain duration. As mentioned previously, the sampling circuit utilizes a sampling capacitor for storing the sampled voltage signal for certain duration. However, leakage exists within the sampling capacitor; as time prolongs, the leakage issue aggravates, and consequently the stored voltage signal within the sampling capacitor is deteriorated to a degree such that errors are likely to occur in the follow-up process. For instances, under light load or no load, power supply 10 of the present invention enters the burst mode in which several switching cycle periods, referred to as skipping periods, are skipped before power switch 14 is resumed to switch for a single or multiple switching cycle periods. This way, the more the skipping periods, the less power power switch 14 consumes as the frequency of the switching operation of power switch 14 is reduced.

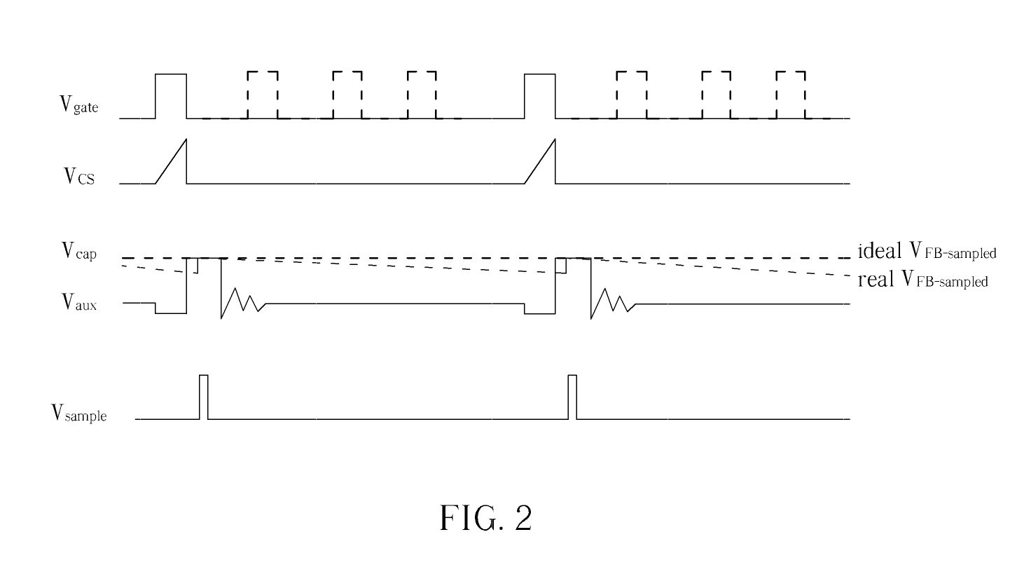

FIG. 2 is a waveform diagram illustrating the voltage signals at different nodes of the power supply. As illustrated in FIG. 2, when voltage signal Vₛₐₘₚₗₑ is periodically triggered, the sampling circuit samples the voltage level of pin FB, which is equivalent as sampling voltage signal Vₐᵤₓ of auxiliary winding 26, and thus the sampling capacitor memorizes a sampled signal V_{cap} of an ideal sampled voltage level represented as “ideal V_{FB-sampled}”. When turning on power switch 14, switching controller 18 determines converted power to be outputted by the secondary winding according to sampled signal V_{cap} stored in the sampling capacitor prior the skipping period. During the skipping period, if the excessive leakage of the sampling capacitor of the sampling circuit is present, the real sampled voltage level represented as “real V_{FB-sampled}” is drastically reduced, so in the first switching cycle after the skipping period, the sampled voltage signal utilized by switch controller 18 as the reference is lower than norm. Consequently, switch controller 18 erroneously determines that the adjusting voltage outputted by the secondary winding is also lower than norm and outputs more energy than desired.

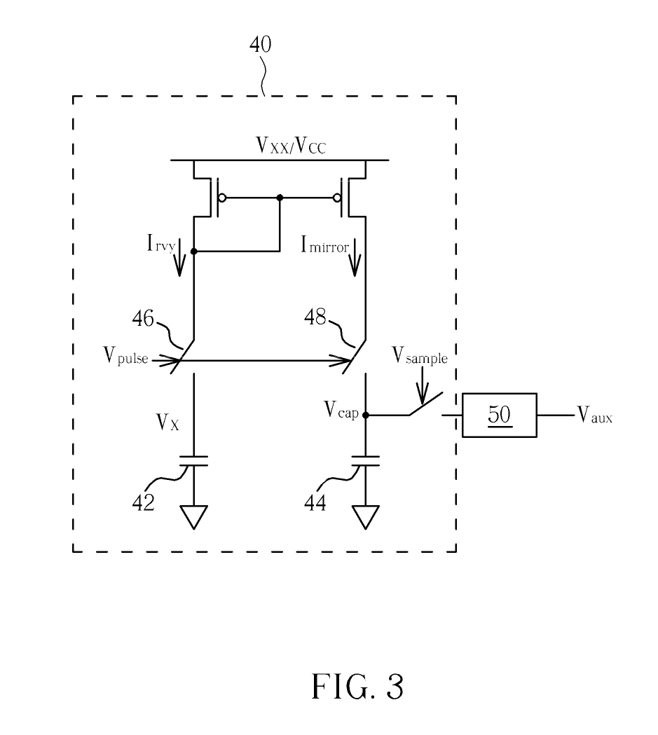

FIG. 3 is a diagram illustrating an embodiment of sampling circuit 40 of switch controller 18 of the present invention. Sampling circuit 40 samples voltage signal Vₐᵤₓ via voltage divider 50. In the present embodiment, voltage divider 50 can be realized with the voltage divider which consists of resistors 30 and 32, as illustrated in FIG. 1. The other components and the circuit structure of the present embodiment are similar to FIG. 1; the relative descriptions are therefore omitted hereinafter. Sampling circuit 40 comprises reference capacitor 42 and sampling capacitor 44 for storing reference signal Vₓ and sampled signal V_{cap} respectively, wherein the trends of voltage variation of reference signal Vₓ and sampled signal V_{cap} should be designed to be the same. For example, during holding, leakage to capacitors would cause both voltage levels of reference signal Vₓ and sampled signal V_{cap} declined. The voltage level of reference signal Vₓ stored in reference capacitor 42 is clamped approximately to a predetermined value during every switching operation. In the present embodiment, the predetermined value equals (Vₓₓ/V_{cc}−Vₜₕₚ), wherein Vₓₓ/V_{cc} presents the voltage of a voltage power source and Vₜₕₚ the threshold value of the P-type Metal Oxide Semiconductor (PMOS) transistor. Through the effect of current mirror, when switches 46 and 48 are turned on together upon receiving pulse signal Vₚᵤₗₛₑ, sampling circuit 40 simultaneously charges reference capacitor 42 and sampling capacitor 44 with recovering current I_{rvy} and mirror current Iₘᵢᵣᵣₒᵣ respectively. Assuming reference capacitor 42 and sampling capacitor 44 are of similar capacitance with the same leakage issue, and the amplitude ratio of the currents (i.e. recovering current I_{rvy} and mirror current Iₘᵢᵣᵣₒᵣ) at the two sides of the current mirror is 1:1, then in the same switching period, both of corresponding reference signal Vₓ and sampled signal V_{cap} suffer with a comparable level of voltage diminution dV. According to the embodiment of the present invention, if reference signal Vₓ is recovered back to the predetermined level of (Vₓₓ/V_{cc}−Vₜₕₚ), which indicates reference signal Vₓ has recovered the voltage level same as voltage diminution dV. Then as the result, sampled signal V_{cap} is also increased by the voltage level same as voltage diminution dV, which effectively nullifies voltage diminution dV caused by the leakage and sampled signal V_{cap} is therefore recovered approximately back to the expected voltage level.

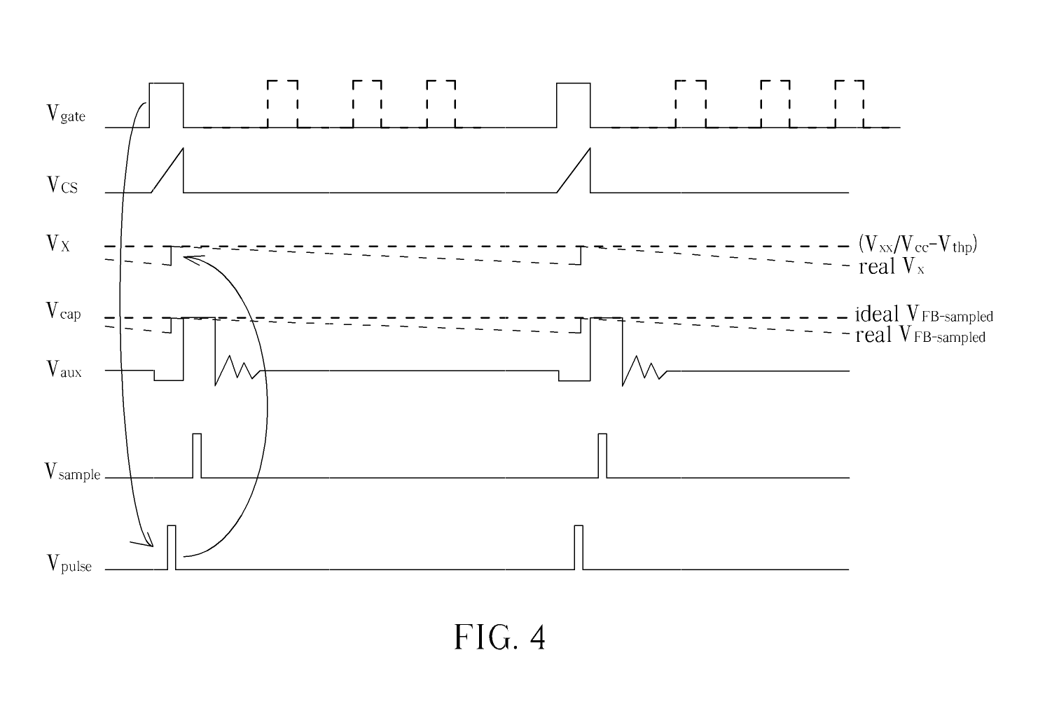

Please refer to FIG. 4. FIG. 4 is a waveform diagram illustrating the signals of sampling circuit 40 of switch controller 18 in FIG. 3. In the above mentioned burst mode, the skipping periods exist between pulses of voltage signal V_{gate}. Voltage signal V_{CS} represents the voltage drop across current detection resistor 16 and the voltage level of voltage signal V_{CS} increases with time after power switch 14 is turned on. Voltage signal Vₐᵤₓ represents the voltage of auxiliary winding 26. The voltage of Reference capacitor 44 samples voltage signal Vₐᵤₓ according to the pulses of voltage signal Vₛₐₘₚₗₑ, wherein the sampling duration is throughout the discharging of auxiliary winding 26 and voltage signal Vₓ represents the reference signal stored in reference capacitor 42.

In the embodiment of the present invention, reference signal Vₓ initially possesses a predetermined voltage level of (Vₓₓ/V_{cc}−Vₜₕₚ). When leakage occurs in reference capacitor 42, the voltage level of reference signal Vₓ declines with time, as indicated by real reference voltage signal real Vₓ. Voltage signal V_{cap} represents the sampled signal stored in sampling capacitor 44; voltage signal V_{cap} will be at constant voltage level “ideal V_{FB-sampled}” if there is no leakage present. However, practically speaking, leakage issue is inevitably to occur in sampling capacitor 44, so the voltage level of real sampled voltage signal represented as “real V_{FB-sampled}” declines accordingly with time. Pulse signal Vₚᵤₗₛₑ is able to turn on switches 46 and 48 at the same time, causing reference signal Vₓ stored in reference capacitor 42 to recover back to the predetermined voltage level of (Vₓₓ/V_{cc}−Vₜₕₚ), as illustrated in FIG. 4. Voltage signal Vₚᵤₗₛₑ is triggered within the charging period of transformer 20. For example, voltage signal Vₚᵤₗₛₑ can be triggered synchronously with voltage signal V_{gate}, or at a short instance after voltage signal V_{gate} is triggered. Due to the effect of the current mirror, when the voltage level of reference signal Vₓ increases, sampled signal V_{cap} also increases by a certain voltage level and in the preferred embodiment of the present invention, sampled signal V_{cap} can be recovered back to approximately the ideal sampled voltage level “ideal V_{FB-sampled}”, for preventing further continuous errors in the follow-up control circuits. Moreover, if no skipping period exists between the switching periods of the power supply, the leakage of the reference capacitor becomes almost negligible and the voltage level of the reference signal remains approximately unchanged without attenuation, so the recovering current I_{rvy} recovering the reference signal will be negligible and the sampled signal of the sampling capacitor, which is charged by negligible mirror current Iₘᵢᵣᵣₒᵣ, is accordingly unaffected.

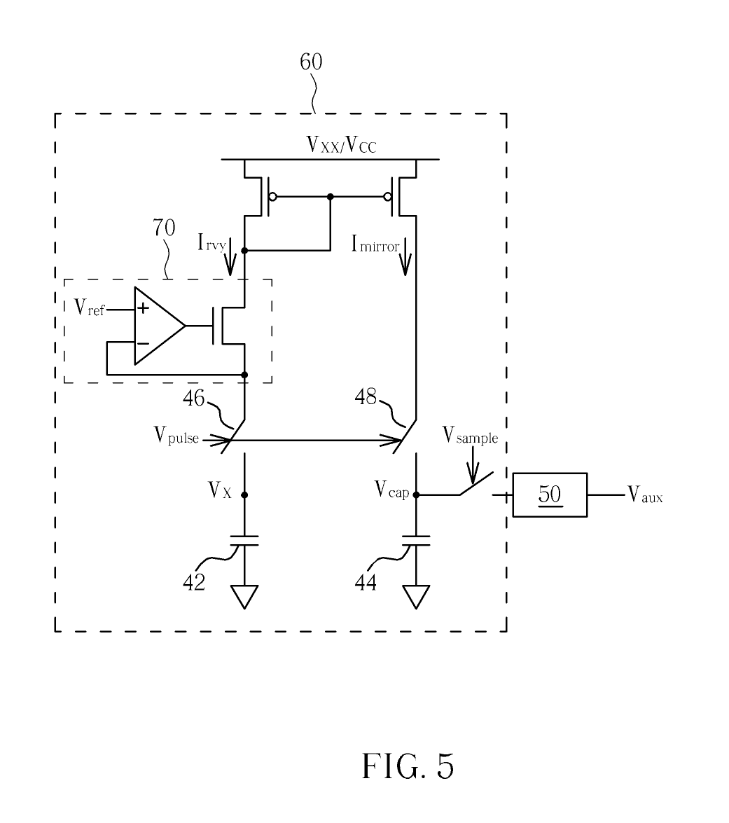

FIG. 5 is diagram illustrating the sampling circuit of switch controller 18 according to another embodiment of the present invention. The present embodiment differs from FIG. 3 of the present invention as reference signal Vₓ of the reference capacitor can have different predetermined voltage levels. Compare to the constant predetermined voltage level of (Vₓₓ/V_{cc}−Vₜₕₚ), sampling circuit 60 utilizes voltage follower circuit 70 so the predetermined voltage level of the reference signal Vₓ approximately equals the voltage level of preset signal V_{ref}. Therefore the voltage level of reference signal Vₓ can be set differently according to preset signal V_{ref}. The operations in the circuit of FIG. 5 are similar to those of the FIG. 3 and can be derived and known by those skilled in the art, so the relative description is therefore omitted hereinafter.

All embodiments of the present invention are applicable to any sampling circuits as long as within the holding period of the sampling capacitor of the sampling circuit, reference signal Vₓ of the reference capacitor is able to recover back to a predetermined voltage level and sampled signal V_{cap} is also adjusted accordingly to compensate the electrical energy lost due to the leakage of the sampling capacitor. In addition, the capacitance of the sampling capacitor does not necessarily have to be identical to the reference capacitor. For instances, if the capacitance ratio of the sampling capacitor and the reference capacitor is 2:1, then as long as the current ratio of the sampling capacitor and the reference capacitor within the current mirror is also set to 2:1, the sampled signal can still be adjusted with the voltage level identical to that of the reference signal is recovered. In another embodiment, the voltage level of the sampled signal can also be adjusted to be higher than the original sampled signal, for achieving over compensation. For example, when the reference signal Vₓ is recovered with a recovery level, the sampled signal is synchronously adjusted with an adjusting level higher than the recovery level. This way, when the power supply is under light load or no load, the power supply outputs a voltage that is lower than expected.

Although the above mention embodiments are based on the fly-back structure, the present invention is not only limited to fly-back-based circuits, but also to other power supply structures such as booster or buck.

Those skilled in the art will readily observe that numerous modifications and alterations of the device and method may be made while retaining the teachings of the invention.

What is claimed is:

1. A sampling circuit, comprising:
a sampling capacitor, for sampling a voltage signal to store a sampled signal; and
a voltage compensation circuit, comprising:
a reference capacitor, for storing a reference signal having a predetermined voltage level; and
a compensation circuit, for recovering the voltage level of the reference signal back to the predetermined voltage level with a recovering level, and simultaneously adjusting a voltage level of the sampled signal with an adjusting level;
wherein the recovering level and the adjusting level have a constant ratio.

2. The sampling circuit of claim 1, wherein the sampling capacitor periodically samples the voltage signal.

3. The sampling circuit of claim 1, wherein the compensation circuit periodically recovers the voltage level of the reference signal back to the predetermined voltage level.

4. The sampling circuit of claim 1, wherein the compensation circuit comprises:
a current mirror, for providing a recovering current and a mirror current proportional to the recovering current; and
a control circuit, for utilizing the recovering current to recover the voltage level of the reference signal back to the predetermined voltage level, and utilizing the mirror current to adjust the voltage level of the sampled signal.

5. The sampling circuit of claim 4, wherein the voltage compensation circuit further comprises a voltage preset circuit, coupled to the compensation circuit, for setting the predetermined voltage level.

6. The sampling circuit of claim 5, wherein the voltage preset circuit is a voltage follower.

7. A control method, for controlling a switching-mode power supply, the switching-mode power supply comprising a transformer, coupled to an input voltage source, controlled by a switch to charge or discharge for generating an output voltage source, the control method comprising:
providing a sampling capacitor;
sampling a voltage signal with the sampling capacitor and storing a sampled signal accordingly;
adjusting a voltage level of the sampled signal stored in the sampled capacitor with an adjusting level prior next sampling the voltage signal; and
adjusting a voltage level of the output voltage source according the adjusted sampled signal.

8. The control method of claim 7, wherein adjusting the voltage level of the sampled signal stored in the sampled capacitor by the adjusting level comprises:
adjusting the voltage level of the sampled signal with the adjusting level during charging of the transformer.

9. The control method of claim 8, wherein sampling the voltage signal with the sampling capacitor comprises:
sampling the voltage signal with the sampling capacitor during discharging of the transformer.

10. The control method of claim 7, further comprising:
providing a reference capacitor, for storing a reference signal having a predetermined voltage level; and
recovering the voltage level of the reference signal back to the predetermined voltage level with a recovering level prior sampling the voltage signal with the sampling capacitor, and synchronously adjusting the voltage level of the sampled signal with the adjusting level, wherein the adjusting level and the recovering level have a constant ratio.

11. The control method of claim 10, wherein the adjusting level is higher than the recovering level.

12. The control method of claim 10, further comprising:
utilizing a pulse signal to recover the voltage level of the reference signal to the predetermined voltage level, and synchronously adjusting the voltage level of the sampled signal.

13. A control method, comprising:
providing a sampling capacitor;
sampling a voltage signal with the sampling capacitor and storing a sampled signal accordingly; and
adjusting a voltage level of the sampled signal stored in the sampled capacitor with an adjusting level prior next sampling the voltage signal.

14. The control method of claim 13, further comprising:
providing a reference capacitor, for storing a reference signal having a predetermined voltage level; and
recovering the voltage level of the reference signal back to the predetermined voltage level with a recovering level prior sampling the voltage signal with the sampling capacitor, and synchronously adjusting the voltage level of the sampled signal with the adjusting level, wherein the adjusting level and the recovering level have a constant ratio.

15. The control method of claim 14, wherein the adjusted voltage level of the sampled signal with the adjusting level is higher than the voltage level of the sampled signal prior adjustment.

16. The control method of claim 14, further comprising:
utilizing a pulse signal to recover the voltage level of the reference signal to the predetermined voltage level, and synchronously adjusting the voltage level of the sampled signal.
